(19) United States
(12) Patent Application Publication
(10) Pub. No.: US 2025/0341550 A1
(43) Pub. Date: Nov. 6, 2025

(54) SYSTEMS AND METHODS FOR PERFORMING RAIL POWER TELEMETRY IN A SYSTEM-ON-A-CHIP (SOC)

(71) Applicant: QUALCOMM INCORPORATED, San Diego, CA (US)

(72) Inventors: Vijayakumar Ashok DIBBAD, Bangalore (IN); Mahadevamurty NEMANI, San Diego, CA (US); Matthew SEVERSON, Austin, TX (US)

(21) Appl. No.: 18/655,101

(22) Filed: May 3, 2024

(51) Int. Cl. G01R 19/10

(52) U.S. Cl. CPC G01R 19/10

(57) ABSTRACT

Systems and methods are provided for performing rail power telemetry in an SoC by providing subsystems of the SoC with circuitry that senses an average of the respective output voltage delivered by a voltage regulator to the respective subsystem over a predetermined time period and uses the respective sensed average output voltage to calculate a load current on the respective load line.

### DESCRIPTION OF THE RELATED ART

A computing device may include multiple processor-based subsystems. Such a computing device may be, for example, a portable computing device (“PCD”), such as a laptop or palmtop computer, a cellular telephone or smartphone, a portable digital assistant, a portable game console, etc. Still other types of PCDs may be included in automotive and Internet-of-Things (“IoT”) applications. A computing device may also be a stationary computer, such as a personal computer (PC) or various types of desktop computers or workstation computers.

Such processor-based subsystems may be included within the same integrated circuit chip or in different chips. A “system-on-a-chip”, or “SoC”, is an example of one such chip that integrates numerous subsystems to provide system-level functionality. For example, an SOC may include one or more types of processors, such as central processing units (“CPU”s), graphics processing units (“GPU”s), digital signal processors (“DSP”s), and neural processing units (“NPU”s). An SOC may include other subsystems as well, such as a transceiver or “modem” subsystem that provides wireless connectivity, a memory subsystem, etc.

SoC power management solutions use rail power telemetry systems to dynamically adapt power budgets for subsystems of the SoC that require voltage regulation, such as the GPUs, the NPUs and the CPU cores, for example. Rail power telemetry systems generally interface the SoC with voltage regulators. The voltage regulators can be part of a power management IC (PMIC) that is external to the SoC or they can be part of one or more other types of ICs.

Current rail power telemetry systems sense the load currents being used by the subsystems of the SoC and use built-in dynamic adjustment circuits that dynamically adjust the output voltages delivered to the subsystems based on the sensed current values to maintain the supply voltages for the subsystems at desired levels. Different configurations of rail power telemetry systems are used for this purpose. One known configuration uses a single interface between the PMIC and the SOC for interfacing all of the voltage regulators of the PMIC with the subsystems of the SoC. Another known configuration of rail power telemetry systems uses dedicated interfaces for interfacing each voltage regulator with a respective subsystem of the SoC.

A disadvantage of using the common-interface configuration is that the periodic telemetry readings that are transmitted over the interface constrain the bandwidth (BW) of the interface and create interface latencies because telemetry readings and all other communications between the PMIC and the SoC are sent over the common interface. These interface latencies detrimentally impact power management efficiency and performance.

A disadvantage of using the dedicated-interface configuration is that although it has reduced interface latencies, there are increased costs associated with the increased number of pins and logic needed on the PMIC and on the SoC to implement the dedicated interfaces. In addition, the number of pins and logic needed to implement the dedicated interfaces increases as the number of subsystems that need voltage regulation increases.

### SUMMARY OF THE DISCLOSURE

Systems, methods, and other examples are disclosed for performing rail power telemetry in an SoC.

An exemplary embodiment of the method comprises, in a subsystem of the SoC, sensing an average of an output voltage delivered to the subsystem over a predetermined time period over a load line by a voltage regulator. The method may further comprise using at least the average of the respective output voltage to calculate a load current on the respective load line.

An exemplary embodiment of the system comprises at least one subsystem disposed on the SoC and electrically coupled to a load line over which an output voltage is delivered to the subsystem by a voltage regulator. The subsystem comprises voltage sensing and averaging circuitry and arithmetic logic. The voltage sensing and averaging circuitry is configured to sense an average of the output voltage delivered to the subsystem over a predetermined time period. The arithmetic logic is configured to use at least the average of the output voltage to calculate a load current on the load line.

An exemplary embodiment of a computer program for execution by a processor for performing rail power telemetry in an SOC comprises first and second sets of computer instructions. The computer program is embodied on a non-transitory computer readable medium. A voltage regulator delivers an output voltage to a subsystem of the SoC via a load line. The subsystem comprises processing logic for executing the computer instructions. The first set of computer instructions obtains an average of the respective output voltage delivered to the subsystem over a predetermined time period. The second set of computer instructions calculates a load current on the load line based at least on the average of the output voltage calculated by the first set of computer instructions.

These and other features and advantages will become apparent from the following description, drawings and claims.

### BRIEF DESCRIPTION OF THE DRAWINGS

In the Figures, like reference numerals refer to like parts throughout the various views unless otherwise indicated.

FIG. 1 illustrates a block diagram of a rail power telemetry system that has a dedicated-interface configuration for a 1:1 arrangement between voltage regulators and subsystems of an SoC.

FIG. 2 is a load current vs. output voltage plot that depicts the manner in which load currents sensed by circuitry of the voltage regulators shown in FIG. 1 are used by the voltage regulators to dynamically adjust the output voltages provided on load lines to the subsystems.

FIG. 3 is a block diagram of the rail power telemetry system of the present disclosure in accordance with a representative embodiment.

FIG. 4 is a flow diagram representing the method for performing rail power telemetry in an SoC in accordance with a representative embodiment.

FIG. 5 is a block diagram of the circuitry 320 and 330 shown in FIG. 3 in accordance with a representative embodiment.

FIG. 6 is a block diagram of the circuitry 320 and 330 shown in FIG. 3 in accordance with another representative embodiment.

FIG. 7 illustrates an example of a PCD that comprises the SoC shown in FIG. 3 having the subsystems shown in FIG. 3 configured to perform the method represented by the flow diagram of FIG. 4.

### DETAILED DESCRIPTION

Representative embodiments of the present disclosure are directed to a system and method for performing rail power telemetry in an SoC by providing subsystems of the SoC with circuitry that senses an average of the respective output voltage delivered by a voltage regulator to the respective subsystem over a predetermined time period and uses the respective sensed average output voltage to calculate a load current on the respective load line.

A detailed discussion of representative embodiments of the power rail telemetry system and method are described below with reference to the figures. In the following detailed description, for purposes of explanation and not limitation, exemplary, or representative, embodiments disclosing specific details are set forth to provide a thorough understanding of an embodiment according to the present teachings. The word “exemplary” is used herein to mean “serving as an example, instance, or illustration.” The words “illustrative” or “representative” may be used herein synonymously with “exemplary.” Any aspect described herein as “exemplary” is not necessarily to be construed as preferred or advantageous over other aspects. However, it will be apparent to one having ordinary skill in the art and having the benefit of the present disclosure that other embodiments according to the present teachings that depart from the specific details disclosed herein remain within the scope of the appended claims. Moreover, descriptions of well-known apparatuses and methods may be omitted to not obscure the description of the example embodiments. Such methods and apparatuses are clearly within the scope of the present teachings.

The terminology used herein is for purposes of describing exemplary or representative embodiments only and is not intended to be limiting. The defined terms are in addition to the technical and scientific meanings of the defined terms as commonly understood and accepted in the technical field of the present teachings.

As used in the specification and appended claims, the terms “a,” “an,” and “the” include both singular and plural referents, unless the context clearly dictates otherwise. Thus, for example, “a device” includes one device and plural devices.

Relative terms may be used to describe the various elements' relationships to one another, as illustrated in the accompanying drawings. These relative terms are intended to encompass different orientations of the device and/or elements in addition to the orientation depicted in the drawings.

It will be understood that when an element is referred to as being “connected to” or “coupled to” or “electrically coupled to” another element, it can be directly connected or coupled, or intervening elements may be present.

The term “memory device”, as that term is used herein, is intended to denote a non-transitory computer-readable storage medium that can store computer instructions, or computer code, for execution by one or more processors. References herein to a “memory device” should be interpreted as including one or more memory devices.

A “processor”, as that term is used herein encompasses an electronic component that can execute a computer program or executable computer instructions. References herein to a computer comprising “a processor” should be interpreted as one or more processors. The processor may for instance be a multi-core processor comprising multiple processing cores, each of which may comprise multiple processing stages of a processing pipeline. A processor may also refer to a collection of processors within a single system or distributed amongst multiple systems.

The term “logic”, as that term is used herein, denotes digital circuits, such as digital gate structures, that are combined and configured in a particular manner to achieve one or more functions. For example, control logic can be a combination of digital circuits that have been combined and configured in a particular manner to achieve one or more control functions, either solely in hardware or in a combination of hardware, software and/or firmware.

A computing device may include multiple subsystems, cores or other components. Such a computing device may be, for example, a personal computing device (PCD), such as a laptop or palmtop computer, a cellular telephone or smartphone, a portable digital assistant, a portable game console, an automotive safety system, etc., or a non-portable computing device (NPCD) such as, for example, a PC, a desktop or a workstation computer.

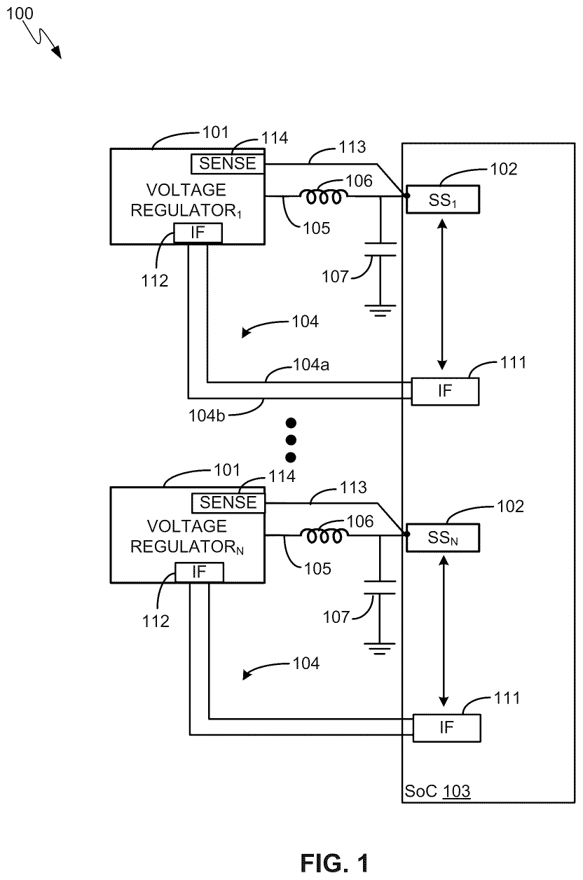

FIG. 1 illustrates a block diagram of a rail power telemetry system 100 that has the aforementioned dedicated-interface configuration. The system 100 comprises N voltage regulators 101 for regulating the supply voltages of N subsystems 102 of an SoC 103 over N dedicated interfaces 104, where N is a positive integer. This configuration is sometimes referred to as a load-line based rail power telemetry system because it uses load-line sensing feedback to determine adjustments that need to be made to the output voltages being provided by the voltage regulators 101 to the respective subsystems 102. The load lines 105 typically comprise circuit elements such as inductors 106 and capacitors 107 that electrically couple the outputs of the voltage regulators 101 to circuitry of the respective subsystems 102.

Each subsystem 102 includes interface logic and pins, represented in FIG. 1 by IF blocks 111. Likewise, each voltage regulator 101 includes interface logic and pins, represented in FIG. 1 by IF blocks 112. These IF blocks 111 and 112 are interconnected by conductor lines 104a and 104b of the interfaces 104. The lines 104a and 104b carry clock and data signals, respectively, between the IF blocks 111 and 112 in order to send instructions, data and acknowledgements between the voltage regulators 101 and the subsystems 102 to obtain telemetry readings. In addition, sensing circuitry 114 in the voltage regulators 101 sense the load currents on the load lines 105 using feedback 113 and use the sensed load currents to calculate adjustments to be made to the output voltages on load lines 105.

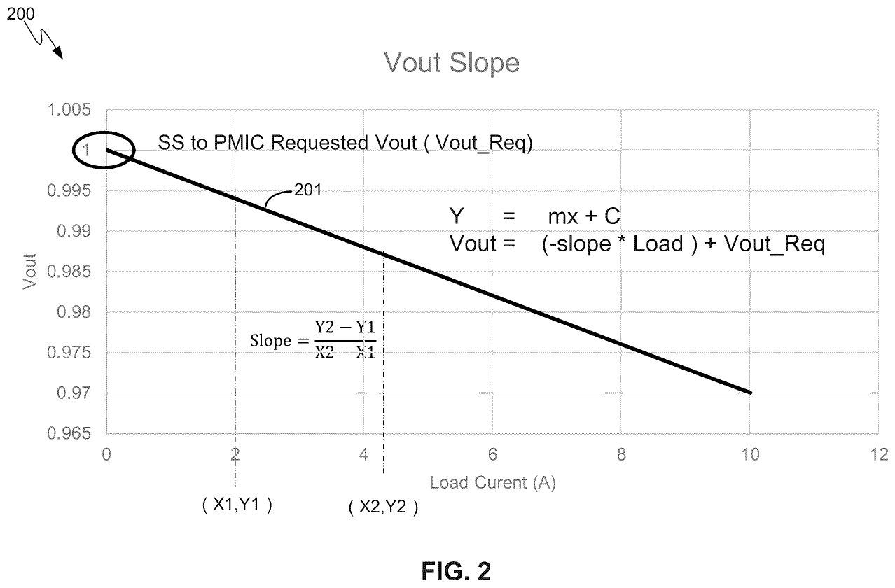

FIG. 2 is a load current vs. output voltage plot 200 that depicts the manner in which the load currents sensed by the voltage regulators 101 are used by the voltage regulators 101 to dynamically adjust the output voltages provided on load lines 105 to the subsystems 102. The plot 200 is a plot of output voltage, V_{OUT}, of the voltage regulator 101 on load line 105 as a function of the load current, I_{LOAD}, on load line 105. In the plot 200, the load current values and the output voltage values are represented on the X-axis and Y-axis, respectively, of a Cartesian coordinate system. The straight line 201 with negative slope corresponds to the following equation:

$${V}_{OUT} = ( - slope \times {I}_{LOAD} ) + {V}_{OUT\_REQ} , \qquad Equation 1$$

where V_{OUT_REQ} is the output voltage that the subsystem 102 is requesting from the voltage regulator 101 (or from the PMIC), -slope is the slope of the line 201 and I_{LOAD} is the sensed load current on load line 105. The slope is a value specified by the original equipment manufacturer (OEM). Based on the known values of -slope and V_{OUT_REQ} and based on the sensed value of I_{LOAD}, the voltage regulator 101 calculates the new V_{OUT} and delivers it to the subsystem 102 on load line 105.

As indicated above, one of the disadvantages of the dedicated-interface configuration shown in FIG. 1 is that the dedicated interfaces 104 increase costs due to the additional pins and logic needed in the PMIC and in the SoC 103 to implement the dedicated interfaces. In addition, there are also interface latencies associated with the communication protocol that is used by the IF blocks 111 and 112 to communicate with one another over lines 104a and 104b. For example, the V_{OUT_REQ} values are values that are sent over the interfaces 104 by the subsystems 102 to the respective voltage regulators 101 (or to the PMIC comprising the voltage regulators 101). Also, current rail power telemetry requirements require the subsystems 102 to obtain the sensed load current values so that the subsystems 102 know their own loads.

In general, the communication protocol for the dedicated interfaces 104 uses handshaking techniques to ensure that the IF blocks 111 and 112 are ready to send or receive data and then the data is sent and received over the interface 104. The receiving IF block 111 or 112 then transmits an acknowledgement of receipt over the interface 104 if receipt was successful. All of this activity consumes BW and creates latencies that detrimentally impact power management and overall performance.

The representative embodiments described below are directed to a rail power telemetry system that preferably has a one-to-one arrangement of voltage regulators to subsystems similar to that of the system 100 shown in FIG. 1, but the need for the dedicated interfaces 104 to enable the subsystems 102 to obtain their own current load values from the voltage regulators 101 is eliminated. Consequently, the interface latencies associated with the interface 104 and their detrimental impact on performance are avoided. Also, the costs associated with the dedicated interfaces are also avoided.

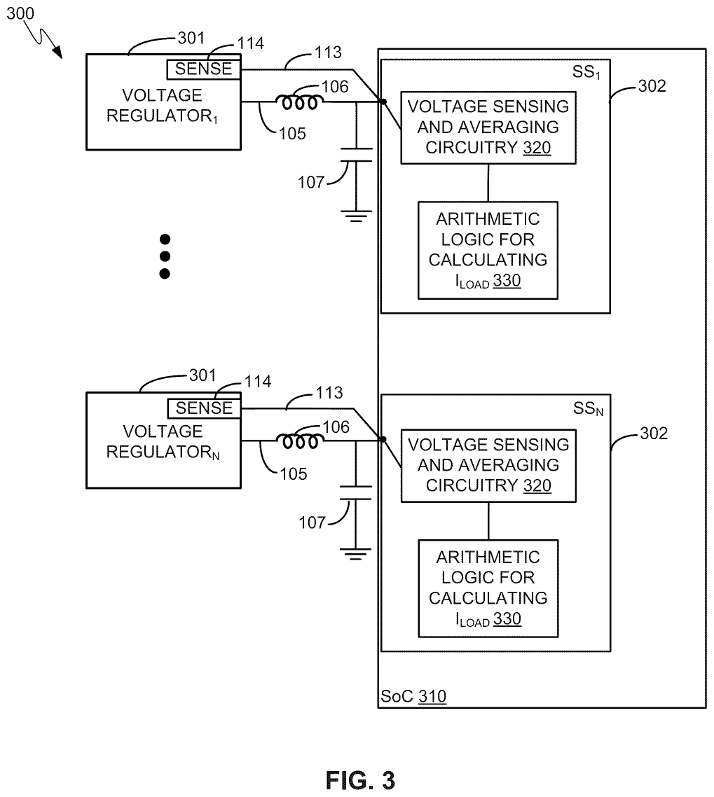

FIG. 3 is a block diagram of the rail power telemetry system 300 of the present disclosure in accordance with a representative embodiment. Like the system 100 shown in FIG. 1, the system 300 comprises N voltage regulators 301 for regulating the supply voltages of N subsystems 302 of an SoC 310. Unlike the system 100 shown in FIG. 1, each subsystem 302 of the system 300 comprises output voltage sensing and averaging circuitry 320 and arithmetic logic 330. The voltage sensing and averaging circuitry 320 is configured to sense the average output voltage V_{OUT_AVG} on the load line 105. The arithmetic logic 330 comprises logic configured to calculate the load current I_{LOAD} on the load line 105 based on V_{OUT_AVG} and based on the known values of V_{OUT_REQ} and slope. As indicated above with reference to FIG. 1, the subsystems 102 used in the dedicated-interface configurations of the type shown in FIG. 1 are configured to provide the V_{OUT_REQ} values to the voltage regulators 101 over the dedicated interfaces 104. Therefore, the subsystems 102 know, or are configured to readily determine, the V_{OUT_REQ} values. The subsystems 302 of the system 300 shown in FIG. 3 are likewise configured to know or to readily determine the V_{OUT_REQ} values. As indicated above, the slope is specified by the OEM and therefore the subsystems 302 know this value.

Using these known values and the measured, or sensed, V_{OUT_AVG} value, the arithmetic logic 330 calculates I_{LOAD} using the following equation derived by rearranging the terms of Eq. 1 above and replacing V_{OUT} in Eq. 1 with V_{OUT_AVG}:

$${I}_{LOAD} = ( {V}_{OUT\_AVG} - {V}_{OUT\_REQ} / - slope \qquad Equation 2$$

Using this equation, the I_{LOAD} values are calculated by the subsystems 302 without having to obtain them from the voltage regulators 302.

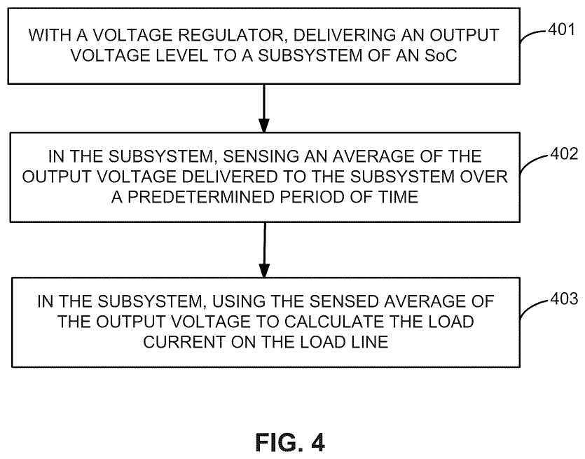

FIG. 4 is a flow diagram representing the method for performing rail power telemetry in an SoC in accordance with a representative embodiment. Block 401 represents the step of, with a voltage regulator, delivering an output voltage V_{OUT} to at least one subsystem of the SoC via a load line. Block 402 represents the step of, in the subsystem, sensing an average of the output voltage V_{OUT_AVG} delivered to the subsystem over a predetermined time period. Block 403 represents the step of, in the subsystem, using the sensed average output voltage V_{OUT_AVG} to calculate a load current I_{Load} on the load line. As indicated above, the load current I_{LOAD} can be calculated using Eq. 2 based on the sensed V_{OUT_AVG} value and on the known values of V_{OUT_REQ} and slope.

It should be noted that steps can be added to the flow diagram of FIG. 4 and steps can be removed from the flow diagram of FIG. 4 without deviating from the scope of the present application. For example, the calculated load current value can be used internally by the subsystem 302 for power management or other purposes and/or forwarded to other subsystems 302 of the SoC 310. Therefore, the process demonstrated by the flow diagram of FIG. 4 can include additional steps not depicted in FIG. 4.

The calculated I_{LOAD} value obtained using Eq. 2 can be used for a number of reasons in the SoC, as will be understood by those of skill in the art in view of the description provided herein. For example, the I_{LOAD} value can be used by a power management system of the SoC to perform power budgeting and/or to perform load peak current management.

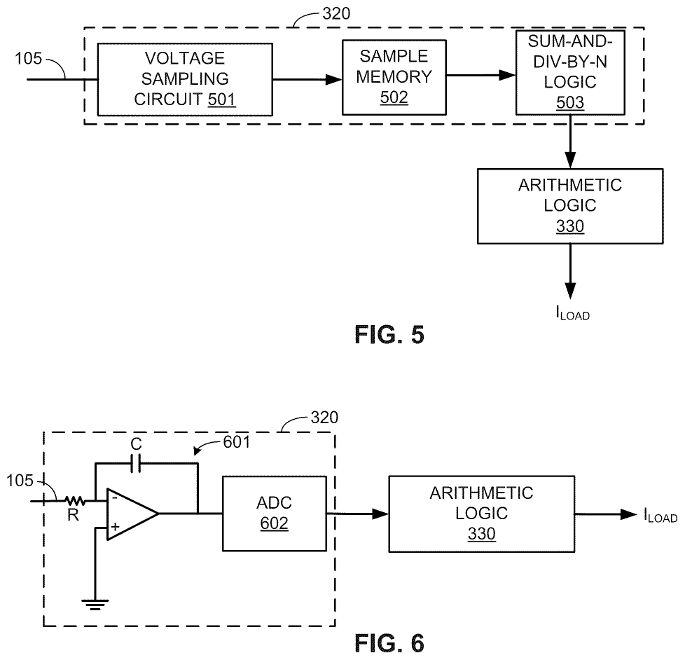

FIG. 5 illustrates a block diagram of the circuitry 320 and 330 shown in FIG. 3 in accordance with a representative embodiment for determining the V_{OUT_AVG} value and using that value in Eq. 2 to calculate the I_{LOAD} value. A variety of digital and analog circuits can be used to perform the operations of circuits 320 and 330 shown in FIG. 3. In accordance with this embodiment, digital logic is used to calculate the V_{OUT_AVG} and I_{LOAD} values. A voltage sampling circuit 501 samples the voltage on the load line 105 over a predetermined period of time, converts the samples into digital values and stores the digital sample values in sample memory 502. Sum-and-divide-by-N logic 503 reads the sample values from the sample memory 502, sums them and divides the sum value by N to obtain V_{OUT_AVG}, where N is the number of samples being used to compute the average. The sample memory 502 is not necessary in all cases, such as if the sum-and-divide-by-N logic 503 includes some type of buffer for holding the sample values obtained over a sample period corresponding to the predetermined time period. The arithmetic logic 330 comprises logic configured to perform the process represented by Eq. 2 to calculate the load current I_{LOAD} on the load line 105 based on V_{OUT_AVG} and based on the known values of V_{OUT_REQ} and slope.

Passive and active analog circuits can also be used to perform the processes of calculating V_{OUT_AVG} and using it in Eq. 2 to calculate I_{LOAD}, as will be understood by those of skill in the art in view of the description provided herein. For example, a network of resistors can be used as a passive averaging circuit and an integrator operational amplifier (Op Amp) with a capacitor in its feedback loop can be used as an active averaging circuit. The predetermined time period over which the voltage on load line 105 is averaged can be based on the loop response time of the voltage regulators. For example, if the loop response time of the voltage regulators is 2 microseconds (μs), the predetermined time period over which the voltage is averaged can also be 2 μs.

FIG. 6 illustrates a block diagram of the circuitry 320 and 330 shown in FIG. 3 in accordance with another representative embodiment for determining the V_{OUT_AVG} value and using that value in Eq. 2 to calculate the I_{LOAD} value. In accordance with this embodiment, an analog integrator Op Amp circuit 601 is used to calculate the V_{OUT_AVG} and I_{LOAD} values. The output of the integrator Op Amp circuit 601 is V_{OUT_AVG}. An analog-to-digital converter (ADC) 602 converts the V_{OUT_AVG} value into a digital V_{OUT_AVG} value and outputs the digital V_{OUT_AVG} value to the arithmetic logic 330, which performs the process represented by Eq. 2 to calculate the load current I_{LOAD} on the load line 105 based on V_{OUT_AVG} and based on the known values of V_{OUT_REQ} and slope.

It should be noted that analog circuitry other than that shown in FIG. 6 can be used to obtain the V_{OUT_AVG} value. As indicated above, a passive circuit comprising a network of resistors can be used to obtain an average voltage value. Also, a combination of analog and digital circuits can be used for this purpose.

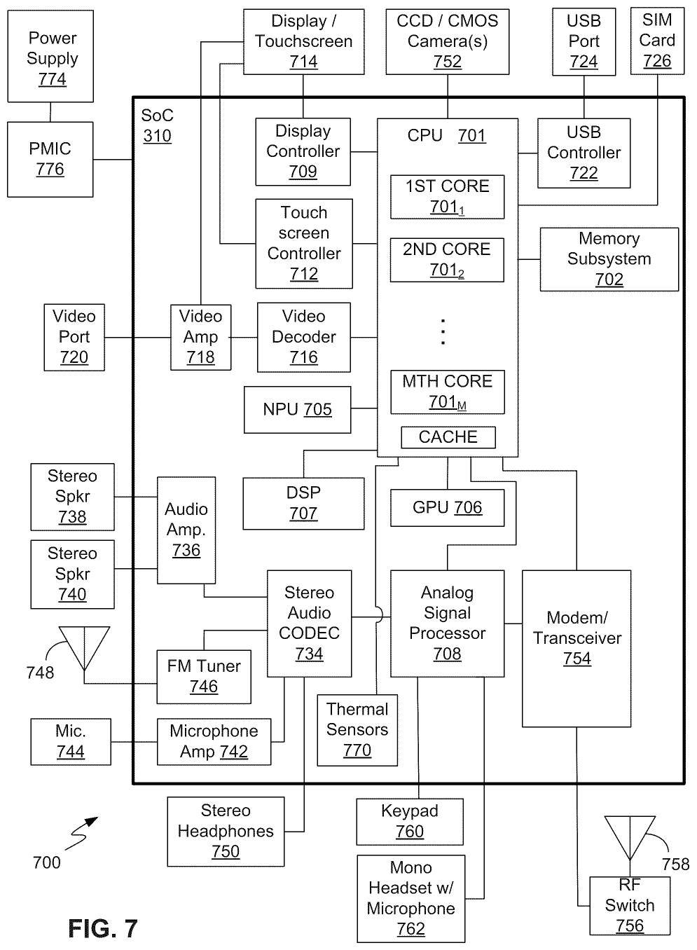

FIG. 7 illustrates an example of a PCD 700, such as a mobile phone or a smartphone, for example, in which exemplary embodiments of systems, methods, computer-readable media, and other examples of the inventive principles and concepts of the present disclosure may be implemented. The PCD 700 comprises the system 300 shown in FIG. 3, which comprises the SoC 310 shown in FIG. 3. For purposes of clarity, some interconnects, signals, etc., are not shown in FIG. 7.

As indicated above, The SoC 310 may include a variety of subsystems, such as, for example, a CPU 701, a memory subsystem 702, an NPU 705, a GPU 706, a DSP 707, an analog signal processor 708, a modem/transceiver 754, etc. The CPU 701 may include one or more CPU cores, such as a first CPU core 7011, a second CPU core 7012, etc., through an M^{th} CPU core 701M.

A display controller 709 and a touch-screen controller 712 may be coupled to the CPU 701. A touchscreen display 714 external to the SoC 310 may be coupled to the display controller 709 and the touch-screen controller 712. The PCD 700 may further include a video decoder 716 coupled to the CPU 701. A video amplifier 718 may be coupled to the video decoder 716 and to the touchscreen display 714. A video port 720 may be coupled to the video amplifier 718. A universal serial bus (“USB”) controller 722 may also be coupled to CPU 701, and a USB port 724 may be coupled to the USB controller 722. A subscriber identity module (“SIM”) card 726 may also be coupled to the CPU 701.

The memory subsystem 702 may be coupled to the CPU 701. The memory subsystem 702 may include both volatile and non-volatile memories. Examples of volatile memories include static random access memory (“SRAM”) and dynamic random access memory (“DRAM”). The one or more memories may include local cache memory and a system-level cache memory (e.g., level 3 (L3) cache memory. The CPU 701 may also include cache memory, e.g., level 1 (L1) and level 2 (L2) cache memories.

A stereo audio CODEC 734 may be coupled to the analog signal processor 708. Further, an audio amplifier 736 may be coupled to the stereo audio CODEC 734. First and second stereo speakers 738 and 740, respectively, may be coupled to the audio amplifier 736. In addition, a microphone amplifier 742 may be coupled to the stereo audio CODEC 734, and a microphone 744 may be coupled to the microphone amplifier 742. A frequency modulation (“FM”) radio tuner 746 may be coupled to the stereo audio CODEC 734. An FM antenna 748 may be coupled to the FM radio tuner 746. Further, stereo headphones 750 may be coupled to the stereo audio CODEC 734. Other devices that may be coupled to the CPU 701 include one or more digital (e.g., CCD or CMOS) cameras 752.

The modem/transceiver 754 may be coupled to the analog signal processor 708 and the CPU 701. An RF switch 756 may be coupled to the modem/transceiver 754 and an RF antenna 758. In addition, a keypad 760 and a mono headset with a microphone 762 may be coupled to the analog signal processor 708. The SoC 310 may have one or more internal or on-chip thermal sensors 770. A power supply 774 and the PMIC 776 may supply power to the SoC 310.

Firmware or software may be stored in any of the above-described memories, or may be stored in a local memory directly accessible by the processor hardware on which the software or firmware executes. The method described above with reference to FIG. 4 may be executed solely in hardware or in a combination of hardware and software and/or firmware. Any software and/or firmware can be stored in any suitable memory device, either local to the subsystem or external to it. Any such memory or other non-transitory storage medium having firmware or software stored therein in computer-readable form may be an example of a non-transitory “computer-readable medium,” as the term is understood in the patent lexicon.

Implementation examples are described in the following numbered clauses:

1. A method for performing rail power telemetry in a system-on-a-chip (SoC), the method comprising:
in a subsystem of the SoC:
   sensing an average of the output voltage delivered to the subsystem over a predetermined time period over a load line by a voltage regulator; and
   using at least the average of the output voltage to calculate a load current on the load line.

2. The method of clause 1, wherein the step of using at least the average of the output voltage to calculate the load current on the load line comprises using the average of the output voltage in combination with a known slope of a load current-to-output voltage relationship specified for the SoC and a known output voltage being requested by the subsystem to calculate the load current.

3. The method of any of clauses 1-2, wherein the voltage regulator comprises circuitry for sensing a load current on the load line and circuitry for calculating a new output voltage to be delivered to the subsystem based at least in part on the sensed load current.

4. The method of clause 3, further comprising:
with the circuitry for sensing a load current on the load line, sensing the load current on the load line; and
with the circuitry for calculating a new output voltage to be delivered to the subsystem based at least in part on the sensed load current, using the sensed load current and a known slope of a load current-to-output voltage relationship specified for the SoC to determine the new output voltage.

5. The method of any of clauses 1-4, wherein the step of sensing an average of the output voltage delivered to the subsystem over a predetermined time period comprises:
sampling the output voltage delivered to the subsystem over the predetermined time period to obtain N sample values, where N is a positive integer that is greater than one;
summing the N sample values to obtain a sum value; and
dividing the sum value by N.

6. The method of any of clauses 1-4, wherein the step of sensing an average of the output voltage delivered to the subsystem over a predetermined time period comprises:
integrating the output voltage delivered to the subsystem over the predetermined time period to obtain the average of the output voltage.

7. The method of any of clauses 1-6, wherein the step of using the average of the output voltage to calculate a load current on the load line comprises processing values in accordance with an equation:

$${I}_{LOAD} = ( {V}_{OUT\_AVG} - {V}_{OUT\_REQ} / - slope ,$$

where I_{Load} is the load current being calculated, V_{OUT}_AVG is the sensed average of the output voltage, V_{OUT}_REQ is a known output voltage being requested by the subsystem and slope is a known value specified for the SoC.

8. A system for performing rail power telemetry in a system-on-a-chip (SoC), the system comprising:
at least one subsystem disposed on the SoC and electrically coupled to a load line over which an output voltage is delivered to the subsystem by a voltage regulator, the subsystem comprising:
voltage sensing and averaging circuitry configured to sense an average of the output voltage delivered to the subsystem over a predetermined time period; and
arithmetic logic configured use at least the average of the output voltage to calculate a load current on the load line.

9. The system of clause 8, wherein the arithmetic logic is configured to use the average output voltage in combination with a known slope of a load current-to-output voltage plot specified for the SoC and a known output voltage being requested by the subsystem to calculate the load current.

10. The system of any of clauses 7-8, wherein the voltage regulator comprises circuitry configured to sense a load current on the load line and circuitry configured to calculate a new output voltage to be output on the load line based at least in part on the sensed load current.

11. The system of clause 10, wherein the circuitry configured to calculate the new output voltage to be delivered to the subsystem based at least in part on the sensed load current uses the sensed load current and a known slope of a load current-to-output voltage relationship specified for the SoC to determine the new output voltage.

12. The system of any of clauses 8-11, wherein the voltage sensing and averaging circuitry comprises:
a voltage sampling circuit configured to sense the output voltage delivered to the subsystem over the predetermined time period to obtain N sample values, where N is a positive integer that is greater than one; and
logic configured to sum the N sample values to obtain a sum value and to divide the sum value by N to obtain the average of the output voltage.

13. The system of any of clauses 8-11, wherein the voltage sensing and averaging circuitry comprises:
an integrator circuit configured to integrate the output voltage delivered to the subsystem over the predetermined time period to obtain the average of the output voltage.

14. The system of any of clauses 8-13, wherein the arithmetic logic is configured to use the average output voltage in accordance with an equation:

$${I}_{LOAD} = ( {V}_{OUT\_AVG} - {V}_{OUT\_REQ} / - slope ,$$

where I_{Load} is the load current being calculated, V_{OUT_AVG} is the sensed average of the output voltage, V_{OUT_REQ} is a known output voltage being requested by the subsystem and slope is a known value specified for the SoC.

15. A computer program for performing rail power telemetry in a system-on-a-chip (SoC), the computer program being embodied on a non-transitory computer readable medium, wherein a voltage regulator delivers an output voltage to a subsystem of the SoC via a load line, and wherein the subsystem comprises processing logic for executing computer instructions, the computer instructions comprising:
a first set of computer instructions for obtaining an average of the output voltage delivered to the subsystem over a predetermined time period; and
a second set of computer instructions for calculating a load current on the load line based at least on the average of the output voltage calculated by the first set of computer instructions.

16. The computer program of clause 15, wherein the second set of computer instructions calculates the load current on the load line based at least on the average of the output voltage calculated by the first set of computer instructions, a known slope of a load current-to-output voltage relationship specified for the SoC and a known output voltage being requested by the subsystem.

17. The computer program of any of clauses 15-16, wherein the first set of computer instructions obtains the average of the output voltage delivered to the subsystem over the predetermined time period by:
obtaining N sample values of the output voltage delivered to the subsystem over the predetermined time period, where N is a positive integer that is greater than one;
summing the N sample values to obtain a sum value; and
dividing the sum value by N.

18. The computer program of any of clauses 15-17, wherein the second set of computer instructions calculates the load current in accordance with an equation:

$${I}_{LOAD} = ( {V}_{OUT\_AVG} - {V}_{OUT\_REQ} / - slope ,$$

where I_{Load} is the load current being calculated, V_{OUT_AVG} is the sensed average of the output voltage, V_{OUT_REQ} is a known output voltage being requested by the subsystem and slope is a known value specified for the SoC.

19. The computer program of any of clauses 15, 16 and 18, wherein the first set of computer instructions obtains the average of the output voltage delivered to the subsystem over the predetermined time period by:
receiving a digitized output of an integrator circuit that averages the output voltage delivered to the subsystem over the predetermined period of time.

20. The computer program of clause 19, wherein the second set of computer instructions calculates the load current in accordance with an equation:

$${I}_{LOAD} = ( {V}_{OUT\_AVG} - {V}_{OUT\_REQ} / - slope ,$$

where I_{Load} is the load current being calculated, V_{OUT_AVG} is the sensed average of the output voltage, V_{OUT_REQ} is a known output voltage being requested by the subsystem and slope is a known value specified for the SoC.

Alternative embodiments will become apparent to one of ordinary skill in the art to which the invention pertains in view of the present disclosure. Therefore, although selected aspects have been illustrated and described in detail, it will be understood that various substitutions and alterations may be made therein.

What is claimed is:

1. A method for performing rail power telemetry in a system-on-a-chip (SoC), the method comprising:
in a subsystem of the SoC:
sensing an average of an output voltage delivered to the subsystem over a predetermined time period over a load line by a voltage regulator; and
using at least the average of the output voltage to calculate a load current on the load line.

2. The method of claim 1, wherein the step of using at least the average of the output voltage to calculate the load current on the load line comprises using the average of the output voltage in combination with a known slope of a load current-to-output voltage relationship specified for the SoC and a known output voltage being requested by the subsystem to calculate the load current.

3. The method of claim 1, wherein the voltage regulator comprises circuitry for sensing a load current on the load line and circuitry for calculating a new output voltage to be delivered to the subsystem based at least in part on the sensed load current.

4. The method of claim 3, further comprising:
with the circuitry for sensing a load current on the load line, sensing the load current on the load line; and
with the circuitry for calculating a new output voltage to be delivered to the subsystem based at least in part on the sensed load current, using the sensed load current and a known slope of a load current-to-output voltage relationship specified for the SoC to determine the new output voltage.

5. The method of claim 1, wherein the step of sensing an average of the output voltage delivered to the subsystem over a predetermined time period comprises:
sampling the output voltage delivered to the subsystem over the predetermined time period to obtain N sample values;
summing the N sample values to obtain a sum value; and
dividing the sum value by N.

6. The method of claim 1, wherein the step of sensing an average of the output voltage delivered to the subsystem over a predetermined time period comprises:
integrating the output voltage delivered to the subsystem over the predetermined time period to obtain the average of the output voltage.

7. The method of claim 1, wherein the step of using the average of the output voltage to calculate a load current on the load line comprises processing values in accordance with an equation:
$${I}_{LOAD} = ( {V}_{OUT\_AVG} - {V}_{OUT\_REQ} / - slope ,$$
where I_{Load} is the load current being calculated, V_{OUT_AVG} is the sensed average of the output voltage, V_{OUT_REQ} is a known output voltage being requested by the subsystem and slope is a known value specified for the SoC.

8. A system for performing rail power telemetry in a system-on-a-chip (SoC), the system comprising:
at least one subsystem disposed on the SoC and electrically coupled to a load line over which an output voltage is delivered to the subsystem by a voltage regulator, the subsystem comprising:
voltage sensing and averaging circuitry configured to sense an average of the output voltage delivered to the subsystem over a predetermined time period; and
arithmetic logic configured use at least the average of the output voltage to calculate a load current on the load line.

9. The system of claim 8, wherein the arithmetic logic is configured to use the average output voltage in combination with a known slope of a load current-to-output voltage plot specified for the SoC and a known output voltage being requested by the subsystem to calculate the load current.

10. The system of claim 8, wherein the voltage regulator comprises circuitry configured to sense a load current on the load line and circuitry configured to calculate a new output voltage to be output on the load line based at least in part on the sensed load current.

11. The system of claim 10, wherein the circuitry configured to calculate the new output voltage to be delivered to the subsystem based at least in part on the sensed load current uses the sensed load current and a known slope of a load current-to-output voltage relationship specified for the SoC to determine the new output voltage.

12. The system of claim 8, wherein the voltage sensing and averaging circuitry comprises:
a voltage sampling circuit configured to sense the output voltage delivered to the respective subsystem over the predetermined time period to obtain N sample values, where N is a positive integer that is greater than one; and
logic configured to sum the N sample values to obtain a sum value and to divide the sum value by N to obtain the average of the output voltage.

13. The system of claim 8, wherein the voltage sensing and averaging circuitry comprises:
an integrator circuit configured to integrate the output voltage delivered to the subsystem over the predetermined time period to obtain the average of the output voltage.

14. The system of claim 8, wherein the arithmetic logic is configured to use the average output voltage in accordance with an equation:
$${I}_{LOAD} = ( {V}_{OUT\_AVG} - {V}_{OUT\_REQ} / - slope ,$$
where I_{Load} is the load current being calculated, V_{OUT_AVG} is the sensed average of the output voltage, V_{OUT_REQ} is a known output voltage being requested by the subsystem and slope is a known value specified for the SoC.

15. A computer program for performing rail power telemetry in a system-on-a-chip (SoC), the computer program being embodied on a non-transitory computer readable medium, wherein a voltage regulator delivers an output voltage to the subsystem of the SoC via a load line, and wherein each of the subsystems comprises processing logic for executing computer instructions, the computer instructions comprising:
a first set of computer instructions for obtaining an average of the output voltage delivered to the subsystem over a predetermined time period; and
a second set of computer instructions for calculating a load current on the load line based at least on the average of the output voltage calculated by the first set of computer instructions.

16. The computer program of claim 15, wherein the second set of computer instructions calculates the load current on the load line based at least on the average of the output voltage calculated by the first set of computer instructions, a known slope of a load current-to-output voltage relationship specified for the SoC and a known output voltage being requested by the subsystem.

17. The computer program of claim 15, wherein the first set of computer instructions obtains the average of the output voltage delivered to the subsystem over the predetermined time period by:
obtaining N sample values of the output voltage delivered to the subsystem over the predetermined time period, where N is a positive integer that is greater than one;
summing the N sample values to obtain a sum value; and
dividing the sum value by N.

18. The computer program of claim 17, wherein the second set of computer instructions calculates the load current in accordance with an equation:
$${I}_{LOAD} = ( {V}_{OUT\_AVG} - {V}_{OUT\_REQ} / - slope ,$$
where I_{Load} is the load current being calculated, V_{OUT_AVG} is the sensed average of the output voltage, V_{OUT_REQ} is a known output voltage being requested by the subsystem and slope is a known value specified for the SoC.

19. The computer program of claim 15, wherein the first set of computer instructions obtains the average of the output voltage delivered to the subsystem over the predetermined time period by:
receiving a digitized output of an integrator circuit that averages the output voltage delivered to the subsystem over the predetermined period of time.

20. The computer program of claim 19, wherein the second set of computer instructions calculates the load current in accordance with an equation:
$${I}_{LOAD} = ( {V}_{OUT\_AVG} - {V}_{OUT\_REQ} / - slope ,$$
where I_{Load} is the load current being calculated, V_{OUT_AVG} is the sensed average of the output voltage, V_{OUT_REQ} is a known output voltage being requested by the subsystem and slope is a known value specified for the SoC.
